(19) United States
(12) Patent Application Publication
(10) Pub. No.: US 2023/0104164 A1
(43) Pub. Date: Apr. 6, 2023

(54) LOW VERTICAL RESISTANCE SINGLE DAMASCENE INTERCONNECT

(71) Applicant: International Business Machines Corporation, Armonk, NY (US)

(72) Inventors: Takeshi Nogami, Schenectady, NY (US); Balasubramanian Pranatharthiharan, Watervliet, NY (US); Prasad Bhosale, Albany, NY (US)

(21) Appl. No.: 17/494,009

(22) Filed: Oct. 5, 2021

(51) Int. Cl. H01L 23/522; H01L 21/768

(52) U.S. Cl. CPC H01L 23/5226; H01L 21/76843; H01L 21/76877

(57) ABSTRACT

Embodiments of the invention include a multi-layer integrated circuit (IC) structure having a back-end-of-line (BEOL) region that includes a dielectric. A single damascene interconnect is in the BEOL region, wherein the single damascene interconnect includes a first line structure in a first line trench of the BEOL region; and a via structure in a via trench of the BEOL region. The first line structure includes a first line element and a first liner. The via structure includes a via element and a via liner. The first line element is physically coupled to inner walls of the first line trench through the first liner. The via element is physically coupled to inner walls of the via trench through the via liner. The first line element is physically coupled and electrically coupled to the via element at a first-line-via interface.

### BACKGROUND

The present invention generally relates to fabrication methods and resulting structures for integrated circuit (IC) wafers. More specifically, the present invention relates to fabrication methods and resulting single damascene interconnect structures having low or reduced vertical resistance.

ICs are fabricated in a series of stages, including a front-end-of-line (FEOL) stage, a middle-of-line (MOL) stage and a back-end-of-line (BEOL) stage. The process flows for fabricating modern ICs are often identified based on whether the process flows fall in the FEOL stage, the MOL stage, or the BEOL stage. Generally, the FEOL stage is where device elements (e.g., transistors, capacitors, resistors, etc.) are patterned in the semiconductor substrate/wafer. The FEOL stage processes include wafer preparation, isolation, gate patterning, and the formation of wells, source/drain (S/D) regions, extension junctions, silicide regions, and liners. The MOL stage typically includes process flows for forming the contacts and other structures that communicatively couple to active regions (e.g., gate, source, and drain) of the device element. Layers of interconnection structures are formed above these logical and functional layers during the BEOL stage to complete the IC. Most ICs need more than one layer of wires/lines to form all the necessary connections, and as many as 5-12 layers are added in the BEOL process. The various interconnect structures in the BEOL layers can include the above-described interconnect lines/wires, as well as metal-filled interconnect vias configured to couple one line/wire to another and/or couple one wafer layer to another.

Vertical resistance is the resistance in a current paths that move back and forth between the top and bottom surfaces of a wafer. In BEOL structures, vertical resistance is typically the current resistance through a via that passes current from one metal line to another.

### SUMMARY

Embodiments of the invention provide a multi-layer integrated circuit (IC) structure having a back-end-of-line (BEOL) region that includes a dielectric. A single damascene interconnect is in the BEOL region, wherein the single damascene interconnect includes a first line structure in a first line trench of the BEOL region; and a via structure in a via trench of the BEOL region. The first line structure includes a first line element and a first liner. The via structure includes a via element and a via liner. The first line element is physically coupled to inner walls of the first line trench through the first liner. The via element is physically coupled to inner walls of the via trench through the via liner. The first line element is physically coupled and electrically coupled to the via element at a first-line-via interface.

Embodiments of the invention provide a method of forming a multi-layer IC structure. The method includes forming a BEOL region including a dielectric, and forming a single damascene interconnect in the BEOL region. Forming the single damascene interconnect includes forming a first line structure in a first line trench of the BEOL region; and forming a via structure in a via trench of the BEOL region. The first line structure includes a first line element and a first liner. The via structure includes a via element and a via liner. Forming the first line element includes physically coupling the first line element to inner walls of the first line trench through the first liner. Forming the via element includes physically coupling the via element to inner walls of the via trench through the via liner. Forming the first line element further includes physically coupling and electrically coupling the first line element to the via element at a first-line-via interface.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 depicts a three-dimensional view of a portion of an IC wafer that incorporates aspects of the invention;

FIG. 2 depicts a top-down view of a low or reduced vertical resistance single damascene interconnect in accordance with embodiments of the invention;

FIG. 3 depicts a cross-sectional view of a low or reduced vertical resistance single damascene interconnect in accordance with embodiments of the invention;

FIGS. 4-7 depict the results of fabrication operations for forming the low or reduced vertical resistance single damascene interconnect shown in FIG. 3, in which:

FIG. 4 depicts a schematic illustration of an IC wafer after fabrication operations according to embodiments of the invention;

FIG. 5 depicts a schematic illustration of an IC wafer after fabrication operations according to embodiments of the invention;

FIG. 6 depicts a schematic illustration of an IC wafer after fabrication operations according to embodiments of the invention; and

FIG. 7 depicts a schematic illustration of an IC wafer after fabrication operations according to embodiments of the invention;

FIG. 8 depicts a cross-sectional view of a low or reduced vertical resistance single damascene interconnect in accordance with embodiments of the invention;

FIGS. 9-10 depict the results of fabrication operations for forming the low or reduced vertical resistance single damascene interconnect shown in FIG. 8, in which:

FIG. 9 depicts a schematic illustration of an IC wafer after fabrication operations according to embodiments of the invention;

FIG. 10 depicts a schematic illustration of an IC wafer after fabrication operations according to embodiments of the invention; and

FIG. 11 depicts a cross-sectional view of a low or reduced vertical resistance single damascene interconnect in accordance with embodiments of the invention;

FIG. 12 depicts a cross-sectional view of a low or reduced vertical resistance single damascene interconnect in accordance with embodiments of the invention; and

FIG. 13 depicts a cross-sectional view of a low or reduced vertical resistance single damascene interconnect in accordance with embodiments of the invention.

The diagrams depicted herein are illustrative. There can be many variations to the diagram or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two- or three-digit reference numbers. With minor exceptions, the leftmost digit(s) of each reference number correspond to the figure in which its element is first illustrated.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the invention, semiconductor devices are used in a variety of electronic applications. ICs are typically formed from various circuit configurations of semiconductor devices (e.g., transistors, capacitors, resistors, etc.) and conductive interconnect layers (known as metallization layers) formed on semiconductor wafers. Alternatively, semiconductor devices can be formed as monolithic devices, e.g., discrete devices. Semiconductor devices and conductive interconnect layers are formed on semiconductor wafers by depositing many types of thin films of material over the semiconductor wafers, patterning the thin films, doping selective regions of the semiconductor wafers, etc.

In contemporary semiconductor fabrication processes, a large number of semiconductor devices and conductive interconnect layers are fabricated. More specifically, during the first portion of chip-making (i.e., the FEOL stage), the individual components (transistors, capacitors, etc.) are fabricated on the wafer. The MOL stage follows the FEOL stage and typically includes process flows for forming the contacts and other structures that communicatively couple to active regions (e.g., gate, source, and drain) of the device element. In the BEOL stage, these device elements are connected to each other through a network of interconnect structures to distribute signals, as well as power and ground. The conductive interconnect layers formed during the BEOL stage serve as a network of pathways that transport signals throughout an IC, thereby connecting circuit components of the IC into a functioning whole and to the outside world. Because there typically isn't enough room on the chip surface to create all of the necessary connections in a single layer, chip manufacturers build vertical levels of interconnects. While simpler ICs can have just a few metallization layers, complex ICs can have ten or more layers of wiring.

BEOL-stage interconnect structures that are physically close to FEOL-stage components (e.g., transistors and the like) need to be small because they attach/join to the components that are themselves very small and often closely packed together. These lower-level lines, which can be referred to as local interconnects, are usually thin and short in length. Global interconnects are higher up in the IC layer structure and travel between different blocks of the circuit. Thus, global interconnects are typically thick, long, and more widely separated local interconnects. Vertical connections between interconnect levels (or layers), called metal-filled vias, allow signals and power to be transmitted from one layer to the next. For example, a through-silicon via (TSV) is a conductive contact that passes completely through a given semiconductor wafer or die. In multi-layer IC configurations, for example, a TSV can be used to form vertical interconnections between a semiconductor device located on one layer/level of the IC and an interconnect layer located on another layer/level of the IC. These vertical interconnect structures include an appropriate metal and provide the electrical connection of the various stacked metallization layers.

As the critical dimensions of the circuit elements in the device level have been decreased, the dimensions of the various interconnect structures (e.g., metal lines/wires, vias, contact elements, and the like) have also reduced. In some cases, the increased packing density mandates the use of sophisticated metal-containing materials in order to improve reliability and provide a sufficiently high conductivity of the individual metal lines and vias. For example, to achieve a desired level of reliability in complex metallization systems, interconnect structures can be formed from copper in combination with a liner/barrier layer(s) in order to achieve the required electrical performance and to minimize electro-migration and/or surface migration failure mechanisms. Copper is a highly conductive material so forming lines and/or vias from high conductivity copper improves overall IC performance. In addition, copper can be fabricated into smaller structures than other conductive materials such as aluminum, which allows interconnect structures to keep pace with transistor size scaling. Copper is also more durable and reliable. The liner/barrier layers surround the particular interconnect structure (e.g., line, contact, and/or via) and serves multiple functions. For example, the liner/barrier can function as a barrier to prevent metals in the interconnect structure from migrating into the surrounding ILD in which the interconnect structures are formed. Additionally, the liner/barrier can provide adhesion between the metal interconnect structure and the surrounding ILD.

Interconnect structures are often formed in a stack. For example, in the BEOL layers, a first line/wire at one level of the BEOL layers can be electrically coupled to a second line/wire at another level of the BEOL layers through a via element. A conventional single damascene interconnect stack fabrication process starts with the deposition of an ILD insulating material (e.g., SiO₂) followed by the sequential creation of trenches in the ILD insulating material, wherein one trench is created for each interconnect stack element (a first line trench, a via trench, and a second line trench). The liner/barrier material is deposited within its corresponding trench, and the remaining trench volume is filled with copper using, for example, a chemical/electroplating process, to thereby form the relevant portion of the interconnect structure stack (e.g., a first line, a via, and a second line). The excess copper is removed to form a flat surface for subsequent processing.

With continued reductions in device dimensions, a limiting factor for the operating speed of the final IC product is no longer the individual transistor element but the electrical performance of the complex interconnect/wiring system that is formed above the device level of the IC. More specifically, as IC feature sizes continue to decrease, the aspect ratio, (i.e., the ratio of height/depth to width) of features such as interconnect structures generally increases. In general, interconnect structures provide current paths that move horizontally in all directions along a major surface of a given level of the IC, as well as current paths that move current vertically from one level of the IC to another. Although the resistivity of interconnect structures in the horizontal and vertical directions must be kept sufficiently low, with narrower, taller (i.e., higher-aspect-ratio) interconnect structures, managing vertical resistivity (or vertical resistance) is a challenge. For example, the liner/barrier and cap materials that are most effective in providing barrier, adhesion and reliability functions are also relatively high resistivity materials that slow down current flow through the interconnect structure stack in the vertical direction. As the aspect ratio of interconnect structure stacks continues to increase, the negative impact of the high resistivity liner/barrier and cap layers of each interconnect element (e.g., a first line, a via, and a second line) in the stack on current flowing through the interconnect stack in the vertical direction also increases.

Accordingly, it is a challenge to provide interconnect scaling without allowing the various interconnect structures to become a bottleneck that reduces IC performance by increasing vertical resistivity (or resistance) and slowing the flow of electrons between IC levels in the vertical direction.

Turning now to an overview of the aspects of the invention, embodiments of the invention reduce vertical resistivity (or vertical resistance) in interconnect structures by providing a single damascene interconnect in which the high resistivity liners/barriers are selectively placed at the interfaces between metal interconnect elements and the surrounding dielectric trench, and selectively omitted at the interfaces between one interconnect element (e.g., a line) and another interconnect element (e.g., a via). By removing the high resistivity liner/barrier elements from the interfaces between single damascene interconnect elements, the vertical resistivity (or vertical resistance) of current moving vertically through such interconnect elements is significantly reduced or eliminated.

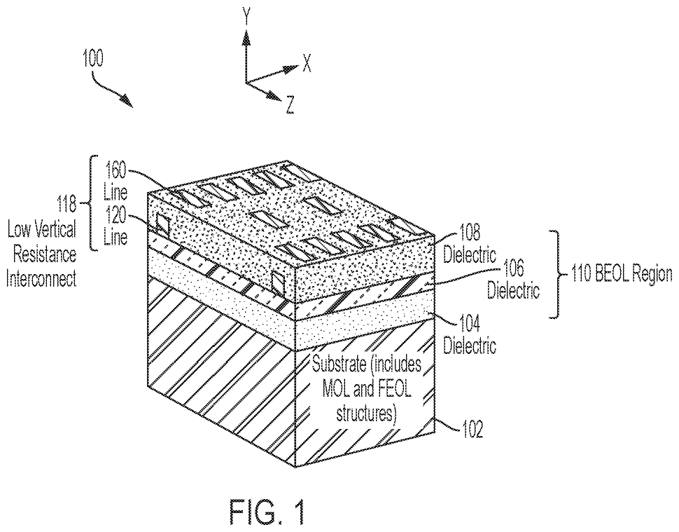

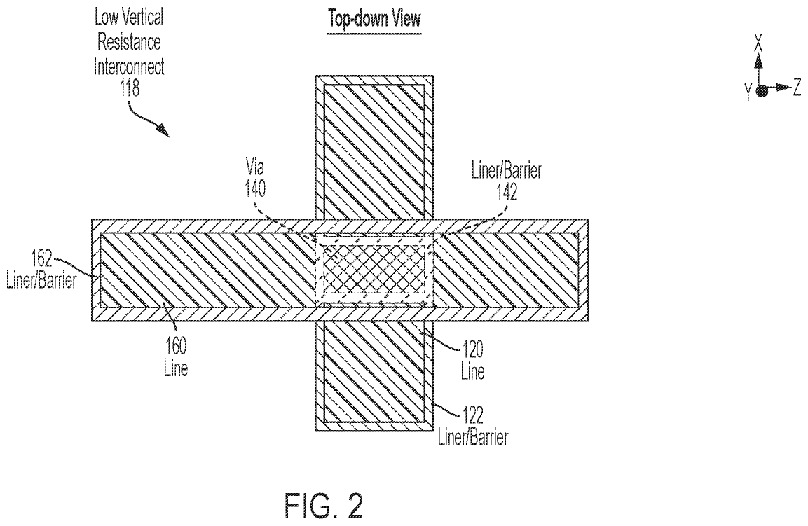

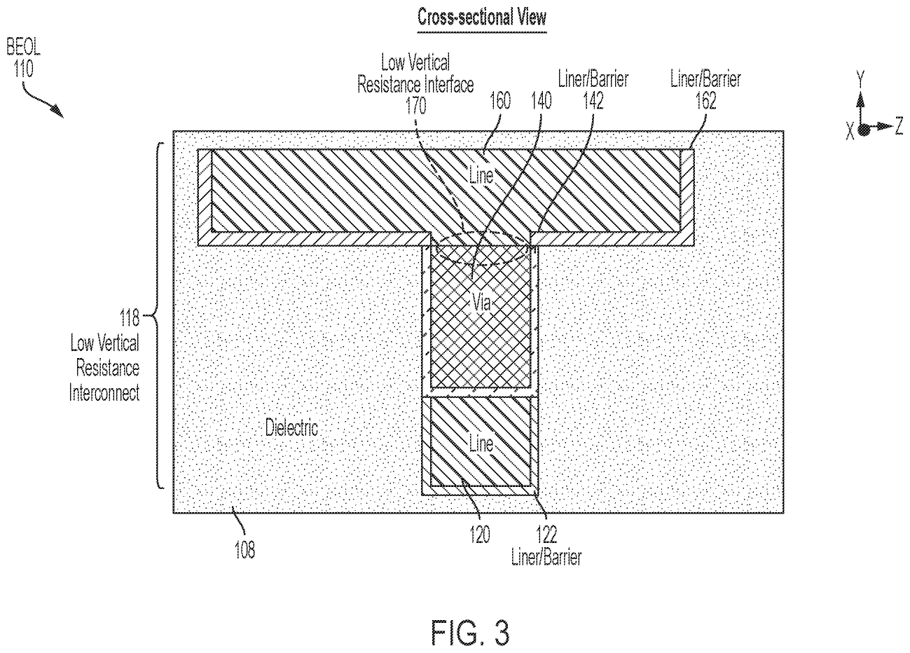

Turning now to a more detailed description of aspects of the present invention, FIG. 1 depicts a portion of an IC wafer 100 having a low vertical resistance (or vertical resistivity) interconnect 118 in accordance with aspects of the invention. The IC wafer 100 includes a substrate 102 having middle-of-line (MOL) and front-end-of-line (FEOL) structures (not shown separately) formed in MOL and FEOL regions (not shown separately) of the substrate 102. A multi-layered BEOL region 110 is formed over the substrate 102. The BEOL region 110 includes a first BEOL dielectric 104, a second BEOL dielectric 106, and a third BEOL dielectric 108, configured and arranged as shown. Although three dielectrics 104, 106, 108 are shown in FIG. 1, the multi-layered BEOL region 110 can be provided with any number of dielectric layers. The third BEOL dielectric 108 includes a network of the novel low vertical resistance interconnects 118 formed therein in accordance with aspects of the invention. In accordance with aspects of the invention, some or all of the layers 104, 106, 108 in the BEOL region 110 can be provided with the novel low vertical resistance interconnects 118. The network of novel low vertical resistance interconnects 118 can be implemented as a network of lines (or wires) 120, metal-filled vias 140 (shown in FIGS. 2 and 3), and lines (or wires) 160, configured to transmit electrical signals throughout the IC wafer 100. In general, the lines 120, 160 conduct current horizontally in a predetermine pattern extending along the Z-axis and/or the X-axis, and the metal-filled vias 140 conduct current vertically along the Y-axis.

In accordance with aspects of the invention, the novel low vertical resistance interconnects 118 are formed in a “single damascene” configuration, wherein the lines 120, the metal-filled vias 140, and the lines 160 are each formed in separate fabrication operations. In accordance with aspects of the invention, line 120 is formed by depositing a blanket dielectric film as a layer of the BEOL region 110, lithographically patterning the blanket dielectric, and applying a reactive ion etched (RIE) to create a line trench that follows the necessary pattern of the line 120. The line trench is coated by a refractory metal liner/barrier (not shown) such as Ta and TaNₓ followed by a thin sputtered metal (e.g., copper) seed layer (not shown separately). The seed layer allows for the electrochemical deposition (ECD) of a thick metal layer that fills up the line trench. Excessive metal is removed and the top surface of the blanket dielectric is planarized by a first planarization process such as a first CMP, thereby forming the line 120. This single damascene process is followed for the remaining vias 140 and lines 160 that form the low vertical resistance interconnects 118. As described in more detail subsequently herein, conventional single damascene processes are modified such that the high resistivity liners are selectively deposited at the interface between the metal interconnect and the dielectric trench, and selectively not deposited at the interfaces between one metal interconnect (e.g., a line) and another metal interconnect (e.g., a via). By removing the high resistivity liner/barrier elements from the interfaces between single damascene interconnect elements (e.g., the line 120, the via 140, and the line 160), the vertical resistivity (or vertical resistance) encountered by current moving vertically through the low vertical resistance interconnects 118 is significantly reduced or eliminated.

FIGS. 2 and 3 depict a top-down view and a cross-sectional view of the low vertical resistance interconnect 118 in accordance with embodiments of the invention. As best shown in the cross-sectional view of FIG. 3, the interconnect 118 is formed in the dielectric 108 as a single damascene structure. The interconnect 118 includes the line 160 electrically coupled through the via 140 to the second line 160. In accordance with aspects of the invention, a liner/barrier 122 is one sidewalls and a bottom surface of the line 120, and a liner/barrier 142 is formed on sidewalls and a bottom surface of the via 140. Additionally a liner/barrier 162 is selectively formed on sidewalls and portions of a bottom surface of the line 160. The liner/barrier layers 122, 142, 162 serves multiple functions. For example, the liner/barrier layers 122, 142, 162 can function as a barrier to prevent metals in the interconnect structures 120, 140, 160 from migrating into the surrounding dielectric 108. Additionally, the liner/barrier layers 122, 142, 162 can provide adhesion between the metal interconnect structures 120, 140, 160 and the surrounding dielectric 108. As shown, the line 162 is selectively present at the interface between the line 160 and the dielectric 108, and is selectively not present at the interface between the line 160 and the via 140. Thus, the interface between the line 160 and the via 140 forms a low vertical resistance interface 170 in accordance with aspects of the invention.

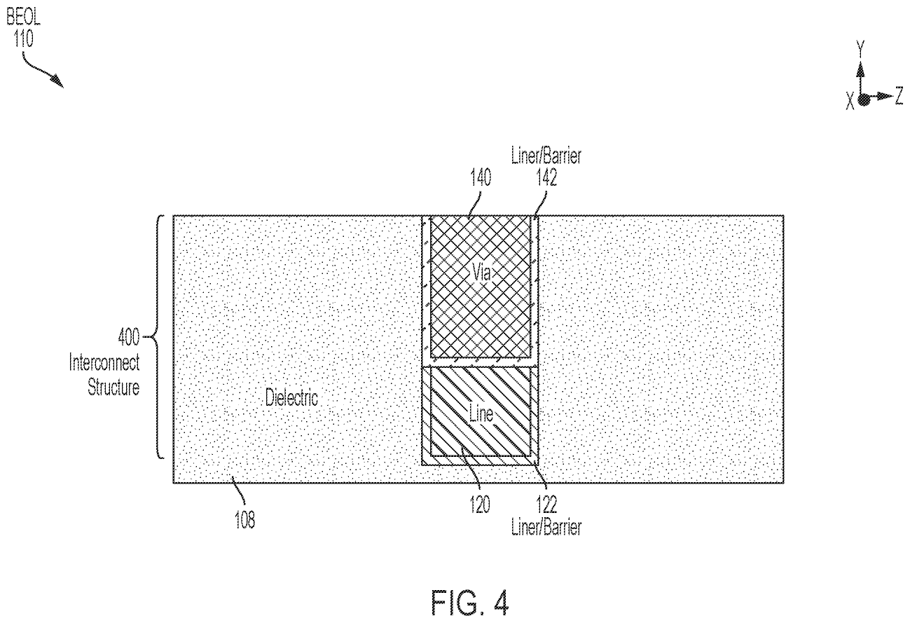

FIGS. 4-7 depict the results of fabrication operations for forming the novel interconnect structure 118 (shown in FIG. 3) in accordance with aspects of the invention. The low vertical resistance interconnect structure 118 while under fabrication is depicted in FIGS. 4-7 as interconnect structure 400. Referring to FIG. 4, a variety of well-known single damascene IC fabrication operations are suitable for forming the structures 400 shown in FIGS. 4-7. Accordingly, in the interest of brevity, such well-known fabrication operations are either omitted or described and illustrated at a high level.

FIG. 4 depicts a schematic illustration of the BEOL region 110 after fabrication operations according to embodiments of the invention, wherein known IC fabrication techniques (e.g., ALD) have been used to form a portion of the dielectric 108. Known single damascene fabrication techniques have also been used to form the line 120, the liner/barrier 122, the via 140, and the liner/barrier 142 in the dielectric 108. After formation of the structures 120, 122, 140, 142, the dielectric 108 shown in FIG. 4 planarized (e.g., using CMP) for subsequent processing.

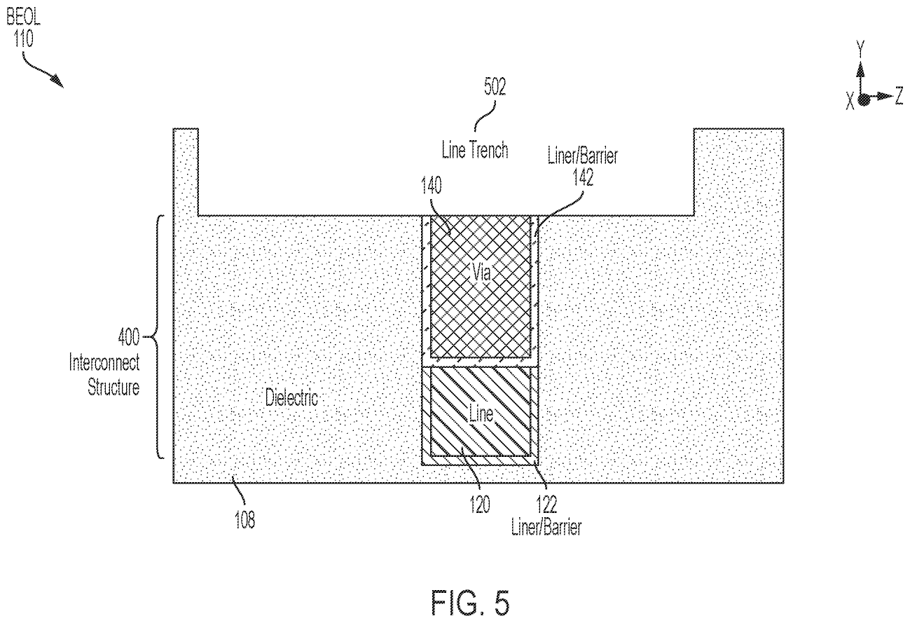

In FIG. 5, known IC fabrication techniques (e.g., ALD) have been used to form another portion of the dielectric 108, and known single damascene IC fabrication techniques (e.g., patterning and RIE) have been used to form a line trench 502 in the dielectric 108, wherein a portion of a bottom surface of the line trench 502 is defined by a top surface of the via 140.

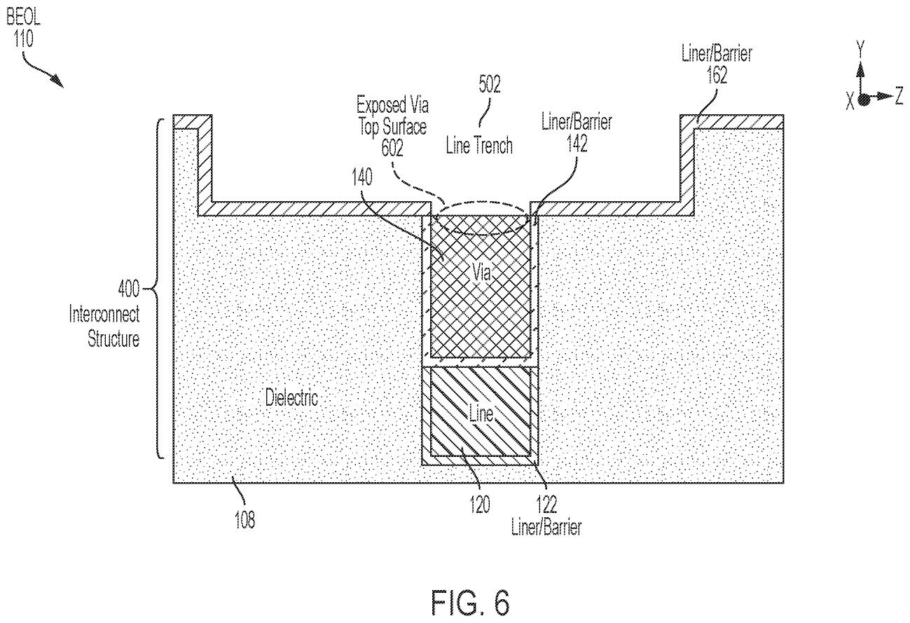

In FIG. 6, a suitable selective metal deposition technique (e.g., patterning, deposition, then pattern removal) has been used to selectively coat the line trench 502 with the refractory metal liner/barrier 162, which can be Ta and TaN. In accordance with embodiments of the invention, the liner/barrier 162 is selectively deposited on inner sidewalls of the portion of the line trench 502 defined by the dielectric 108 but is selectively not deposited on the portion of the line trench 502 defined by the exposed top surface 602 of the via 140.

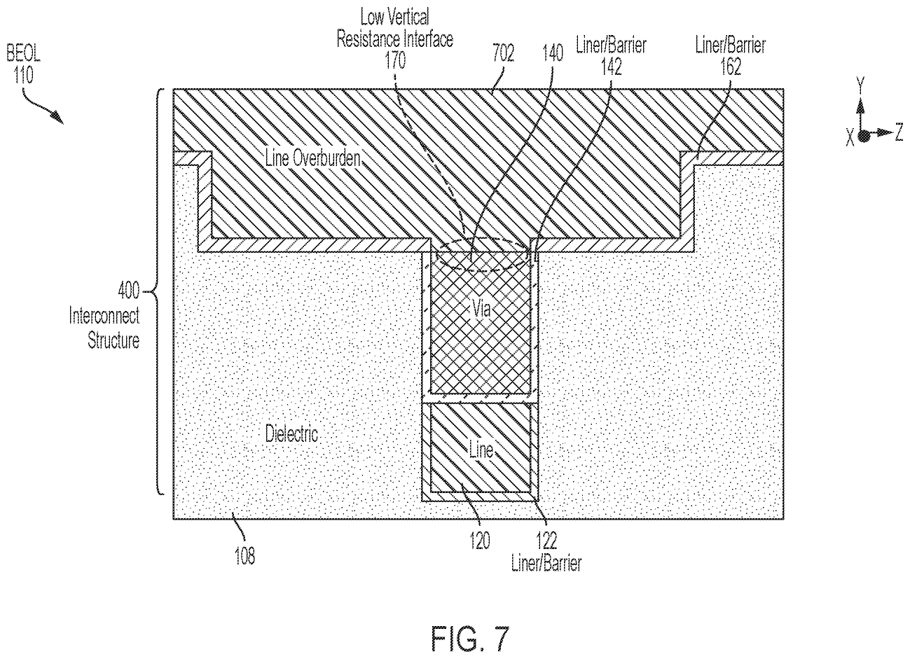

In FIG. 7, known fabrication techniques have been used to form a line overburden 702 within the line trench 502. The overburden 702 can be formed by depositing within the trench 502 a thin sputtered metal (e.g., copper) seed layer (not shown separately). The seed layer allows for the electrochemical deposition (ECD) of the relatively thick line overburden 702 that fills up the line trench 502 and forms the low vertical resistance interface 170. Known semiconductor fabrication techniques are next used to remove excessive metal in the line overburden 702 and planarize the top surface of the BEOL region 110 using a planarization process such as a first CMP, thereby forming the low vertical resistance interconnect structure 118 (shown in FIG. 4) in accordance with aspects of the invention.

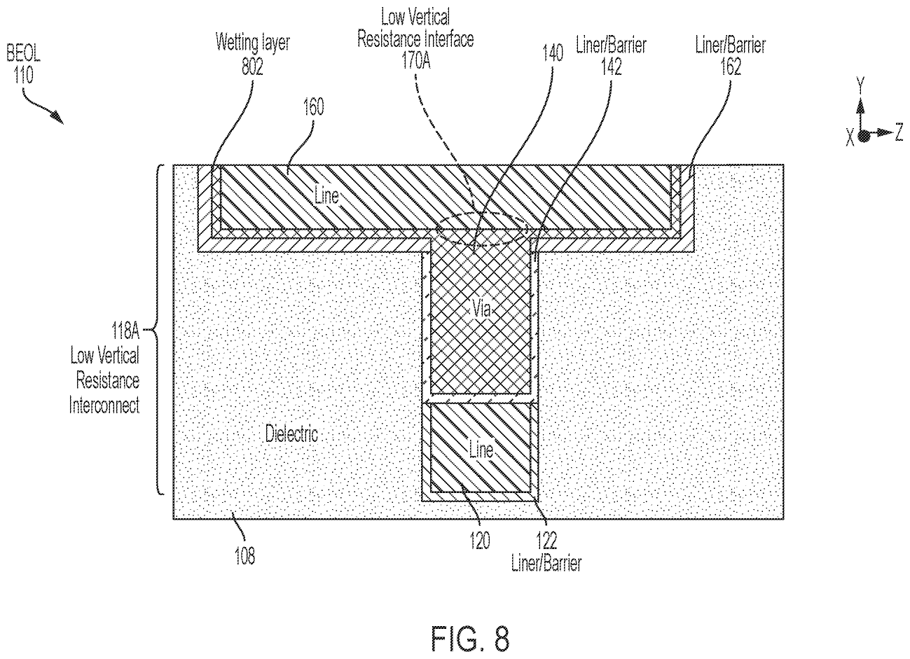

FIG. 8 depict a cross-sectional view of a low vertical resistance interconnect 118A in accordance with embodiments of the invention. The low vertical resistance interconnect 118A is substantially the same as the low vertical resistance interconnect 118 (shown in FIG. 1-7) except a wetting layer 802 is provide between the line 160 and the liner/barrier 162. Accordingly, a low vertical resistance interface 170A is formed as an interface between the liner 160 and the wetting layer 802 that overlaps an interface (also low vertical resistance) between the wetting layer 802 and the via 140.

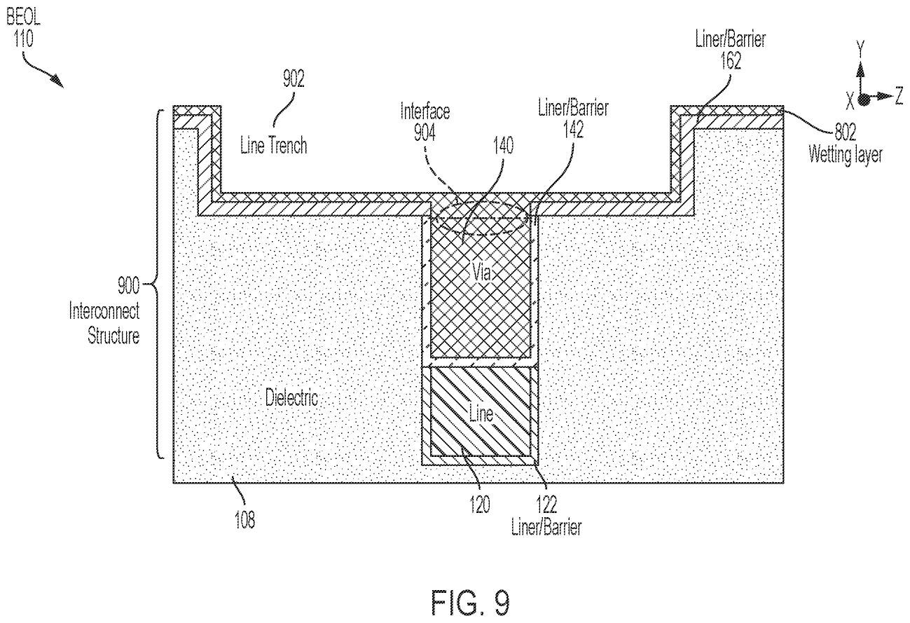

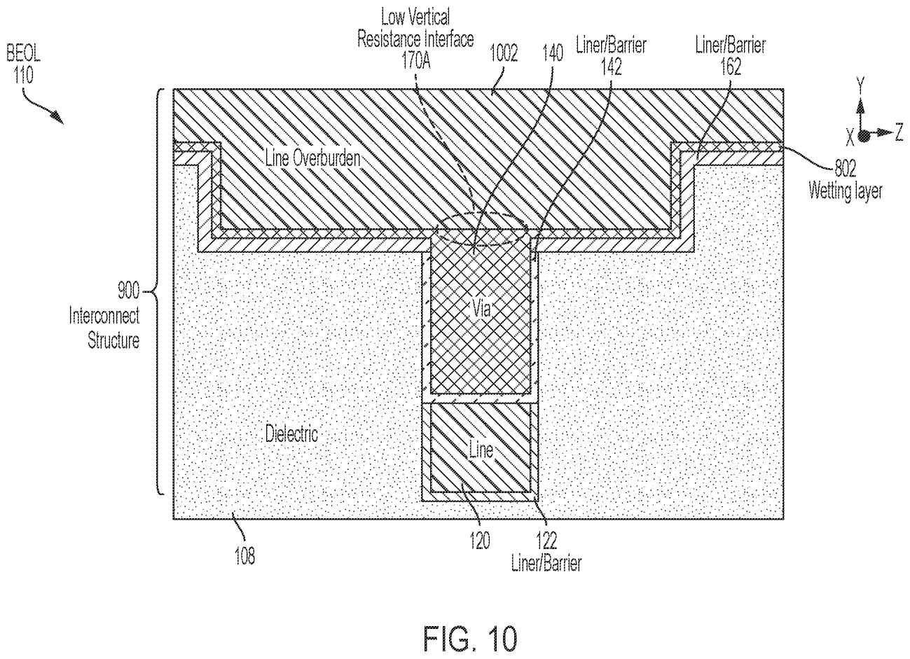

FIGS. 9-10 depict the results of fabrication operations for forming the novel interconnect structure 118A (shown in FIG. 8) in accordance with aspects of the invention. The low vertical resistance interconnect structure 118A while under fabrication is depicted in FIGS. 9-10 as interconnect structure 900. Referring to FIG. 9, the same fabrication operations shown in FIG. 4-6 have been performed. After the operations depicted at FIG. 6, known deposition operations (e.g., ALD) have been used to deposit the wetting layer 802 in the line trench 502, thereby forming a line trench 902 and forming an interface 904 between the top surface of the via 140 and the wetting layer 802. In accordance with aspects of the invention, the interface 904 has low vertical resistance in that its vertical current path is not impeded by a high resistivity material such as the material used to form the liner/barrier 162.

In FIG. 10, known fabrication techniques have been used to form a line overburden 1002 within the line trench 902 (shown in FIG. 9). The overburden 1002 can be formed by using a metallization process to deposit a thin sputtered seed layer (not shown separately), such as copper (Cu), copper manganese (CuMn), copper aluminum (CuAl), and alloys thereof. An electroplating operation (e.g., electrochemical deposition and/or electroless deposition) and a subsequent reflow process are used to fill the line trench 902, create the line overburden 1002, and form the low vertical resistance interface 170A. An anneal can be performed to crystallize the metal in the line overburden 1002. The structure can be polished by chemical mechanical polish to remove the metal overburden and repeated as desired. Known semiconductor fabrication techniques are next used to remove excessive metal in the line overburden 1002 and planarize the top surface of the BEOL region 110 using a planarization process such as a first CMP, thereby forming the low vertical resistance interconnect structure 118A (shown in FIG. 8) in accordance with aspects of the invention.

The wetting layer 802 can be formed from any suitable wetting layer material, including Co, Mo, W, Ta, Ru or other platinum ground materials. The wetting layer 802 assists with the metallization (or formation) of the line 160 depicted in FIGS. 8-10 and described above. In embodiments of the invention, the wetting layer 802 can include any material that wets the metal (e.g., Cu) that forms the line 160. In embodiments of the invention the wetting layer 802 assists with reducing or eliminating metal defects (e.g., voids or gap-fill issues) in the line 160 that can reduce reliability and yield. In general, the wetting layer 802 can include any material that wets a Cu layer. During the previously described reflow process, the wetting layer 802 promotes filling of the grooves at any interface between the wetting layer 802 and another material (e.g., the liner/barrier 162 and/or the line 160), while gaps, voids, and seams are substantially eliminated.

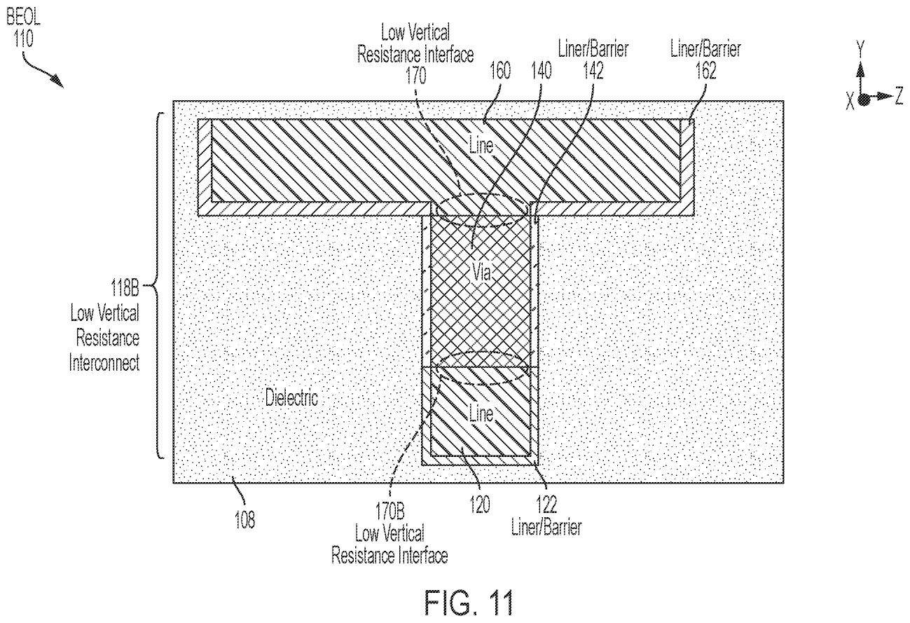

FIGS. 11, 12, and 13 depict low vertical resistance interconnects 118B, 118C, 118D in accordance with aspects of the invention. The low vertical resistance interconnects 118B, 118C, 118D can be fabricated using an appropriate combination of he known single damascene fabrication operations, including the fabrication operations depicted in FIGS. 4-7 and 9-10. Accordingly, in the interest of brevity, the specific details of how the low vertical resistance interconnects 118B, 118C, 118D can be fabricated will not be repeated herein.

In FIG. 11, the low vertical resistance interconnects 118B is substantially the same as the low vertical resistance interconnects 118 except a second low vertical resistance interface 170B is formed by selectively depositing the liner/barrier 142 in substantially the same manner as the liner/barrier 162.

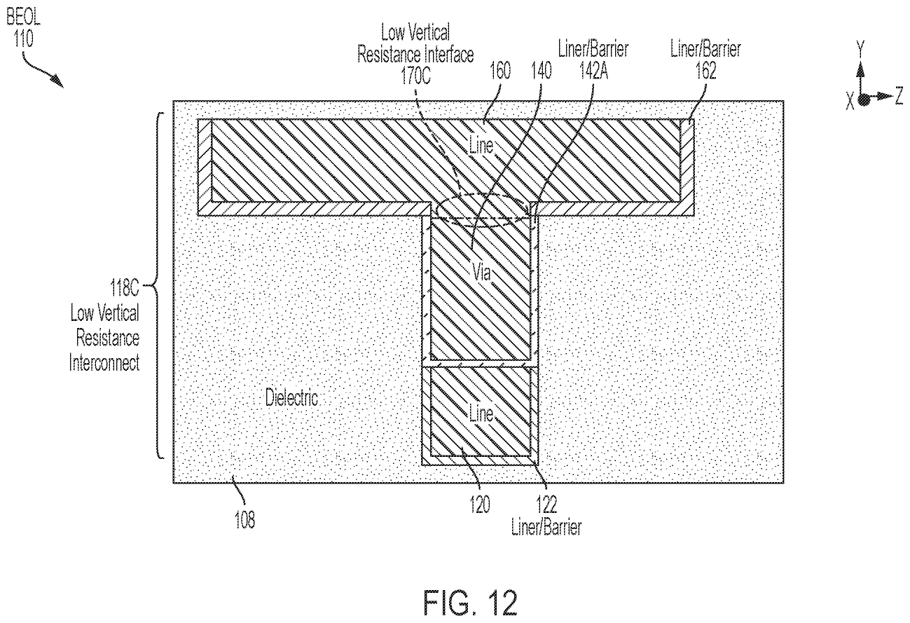

In FIG. 12, the low vertical resistance interconnects 118C is substantially the same as the low vertical resistance interconnects 118 except the line 120, the via 140, and the line 160 are all formed from copper (Cu), thereby forming a low vertical resistance interface 170C. Additionally, the liner/barrier 142A is provided to provide a liner/barrier more suitable to a copper form of the via 140.

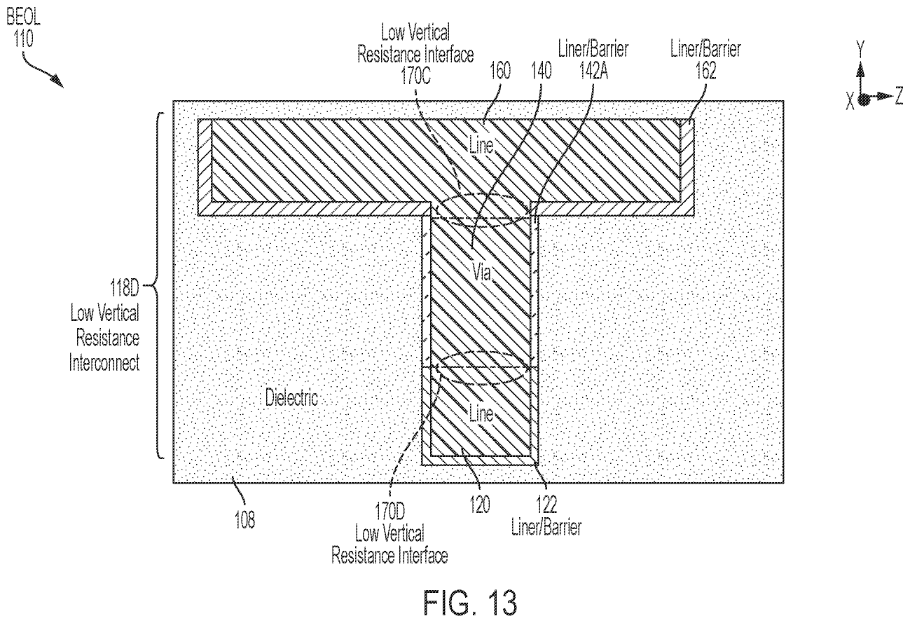

In FIG. 13, the low vertical resistance interconnects 118D is substantially the same as the low vertical resistance interconnects 118C except a second low vertical resistance interface 170D is formed by selectively depositing the liner/barrier 142A in substantially the same manner as the liner/barrier 162.

In accordance with aspects of the invention, the features of the low vertical resistance interconnects 118, 118A, 118B, 118C, 118D can be provided in any combination. For example, although the wetting layer 802 is depicted in the low vertical resistance interconnects 118A, the wetting layer 802 can be incorporated into any of the low vertical resistance interconnects 118, 118B, 118C, 118D. Additionally, although the example implantation of the wetting layer 802 is shown for the line 160, the same wetting layer and its associated functions can be applied to the via 140 and/or the line 120.

In accordance with embodiments of the invention, the lines 120, 160 can be any suitable conductive metal, including but not limited to Cu and Co. In accordance with embodiments of the invention, the via 140 can be any suitable conductive metal, including but not limited to Co, W, Ru, Mo, and the like. In accordance with embodiments of the invention, the liner/barriers 122, 142, 162 can be any suitable barrier/liner material including but not limited TaN. In accordance with embodiments of the invention, the wetting layer 802 can be any suitable wetting material, including but not limited to Co.

The methods and resulting structures described herein can be used in the fabrication of IC chips. The resulting IC chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes IC chips, ranging from toys and other low-end applications to advanced computer products having a display, a keyboard or other input device, and a central processor.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

“Planarization” and “planarize” as used herein refer to a material removal process that employs at least mechanical forces, such as frictional media, to produce a substantially two-dimensional surface. A planarization process may include chemical mechanical polishing (CMP) or grinding. CMP is a material removal process that uses both chemical reactions and mechanical forces to remove material and planarize a surface.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the invention, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), chemical-mechanical planarization (CMP), and the like. Reactive ion etching (RIE), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A multi-layer integrated circuit (IC) structure comprising:
a back-end-of-line (BEOL) region comprising a dielectric; and
a single damascene interconnect in the BEOL region, wherein the single damascene interconnect comprises:
a first line structure in a first line trench of the BEOL region; and
a via structure in a via trench of the BEOL region;
wherein the first line structure comprises a first line element and a first liner;
wherein the via structure comprise a via element and a via liner;
wherein the first line element is physically coupled to inner walls of the first line trench through the first liner;
wherein the via element is physically coupled to inner walls of the via trench through the via liner; and
wherein the first line element is physically coupled and electrically coupled to the via element at a first-line-via interface.

2. The structure of claim 1, wherein:
the first line element comprises a first type of conductive metal; and
the via element comprises a second type of conductive metal.

3. The structure of claim 2, wherein the first type of conductive metal is different from the second type of conductive metal.

4. The structure of claim 1 further comprising a wetting layer in the first line trench.

5. The structure of claim 4, wherein the first line element is physically coupled to the inner walls of the first line trench through the first liner and the wetting layer.

6. The structure of claim 5, wherein the first line element is physically coupled and electrically couple to the via element through the wetting layer.

7. The structure of claim 6, wherein the first line element is physically coupled and electrically coupled to the wetting layer at a first-line-element-wetting-layer interface.

8. The structure of claim 7, wherein the wetting layer is physically coupled and electrically coupled to the via element at a wetting-layer-via-element interface.

9. The structure of claim 7, wherein:
the first line element comprises a first type of conductive metal;
the via element comprises a second type of conductive metal; and
the wetting element comprises a third type of conductive metal.

10. The structure of claim 9, wherein the first type of conductive metal is different from the second type of conductive metal.

11. The structure of claim 10, wherein the second type of conductive metal is the same as the third type of conductive metal.

12. The structure of claim 1 further comprising:
a second line in a second line trench of the BEOL region;
wherein the second line comprises a second line element and a second liner;
wherein the second line element is physically coupled to the inner walls of the first line trench through the first liner;
wherein the via element is physically coupled to the inner walls of the via trench through the via liner; and
wherein the first line element is physically coupled and electrically coupled to the via element at a second-line-via interface.

13. The structure of claim 1 further comprising:
a wetting layer in the first line trench;
wherein the first line element is physically coupled to the inner walls of the first line trench through the first liner and the wetting layer;
wherein the first line element is physically coupled and electrically couple to the via element through the wetting layer;
wherein the first line element is physically coupled and electrically coupled to the wetting layer at a first-line-element-wetting-layer interface; and
wherein the wetting layer is physically coupled and electrically coupled to the via element at a wetting-layer-via-element interface.

14. The structure of claim 13, wherein:
the first line element comprises a first type of conductive metal;
the via element comprises a second type of conductive metal;
the wetting layer comprises a third type of conductive metal; and
the second line element comprises a fourth type of conductive metal.

15. The structure of claim 14, wherein:
the first type of conductive metal is different from the second type of conductive metal; and
the third type of conductive metal is different from the fourth type of conductive metal.

16. A method of forming a multi-layer integrated circuit (IC) structure, the method comprising:
forming a back-end-of-line (BEOL) region comprising a dielectric; and
forming a single damascene interconnect in the BEOL region, wherein forming the single damascene interconnect comprises:
forming a first line structure in a first line trench of the BEOL region; and
forming a via structure in a via trench of the BEOL region;
wherein the first line structure comprises a first line element and a first liner;
wherein the via structure comprise a via element and a via liner;
wherein forming the first line element comprises physically coupling the first line element to inner walls of the first line trench through the first liner;
wherein forming the via element comprises physically coupling the via element to inner walls of the via trench through the via liner; and
wherein forming the first line element further comprises physically coupling and electrically coupling the first line element to the via element at a first-line-via interface.

17. The method of claim 16 further comprising:
forming a wetting layer in the first line trench;
wherein forming the first line element comprises physically coupling the first line element to the inner walls of the first line trench through the first liner and the wetting layer;
wherein forming the first line element further comprises physically coupling and electrically coupling the first line element to the via element through the wetting layer;
wherein forming the first line element further comprises physically coupling and electrically coupling the first line element to the wetting layer at a first-line-element-wetting-layer interface; and
wherein forming the wetting layer further comprises physically coupling and electrically coupling the wetting layer to the via element at a wetting-layer-via-element interface.

18. The method of claim 16 further comprising:
forming a second line in a second line trench of the BEOL region;
wherein the second line comprises a second line element and a second liner;
wherein forming the second line element comprises physically coupling the second line element to the inner walls of the first line trench through the first liner;
wherein forming the via element further comprises physically coupling and electrically coupling he via element to the inner walls of the via trench through the via liner; and
wherein forming the first line element further comprises physically coupling and electrically coupling the first line element to the via element at a second-line-via interface.

19. The method of claim 18 further comprising:
forming a wetting layer in the first line trench;
wherein forming the first line element further comprises physically coupling the first line element to the inner walls of the first line trench through the first liner and the wetting layer;
wherein forming the first line element further comprises physically coupling and electrically coupling the first line element to the via element through the wetting layer;
wherein forming the first line element further comprises physically coupling and electrically coupling the first line element to the wetting layer at a first-line-element-wetting-layer interface; and
wherein the wetting layer is physically coupled and electrically coupled to the via element at a wetting-layer-via-element interface.

20. The method of claim 19, wherein:
the first line element comprises a first type of conductive metal;
the via element comprises a second type of conductive metal;
the wetting layer comprises a third type of conductive metal; and
the second line element comprises a fourth type of conductive element.
